(19) United States
(12) Patent Application Publication
(10) Pub. No.: US 2006/0242530 A1
(43) Pub. Date: Oct. 26, 2006

(54) Method for constructing finite-length low density parity check codes

(75) Inventors: Ben Lu, Plainsboro, NJ (US); Guosen Yue, Plainsboro, NJ (US); Xiaodong Wang, New York, NY (US); Mohammad Madihian, Plainsboro, NJ (US)

Correspondence Address: NEC LABORATORIES AMERICA, INC., 4 INDEPENDENCE WAY, PRINCETON, NJ, 08540, US

(73) Assignee: NEC Laboratories America, Inc., Princeton, NJ (US)

(21) Appl. No.: 11/095,160

(22) Filed: Mar. 31, 2005

(51) Int. Cl. H03M 13/00

(52) U.S. Cl. 714/752

(57) ABSTRACT

A technique for construction of finite-length low-density parity check (LDPC) codes is herein disclosed which advantageously provides a flexible tradeoff of low decoding thresholds and low error-floors.

### BACKGROUND OF INVENTION

The invention relates generally to encoding techniques and code construction.

One of a variety of known error correcting codes is a class of codes known as low density parity check (LDPC) codes. An LDPC code is a linear block code typically specified by a very sparse parity check matrix. The parity check matrix P of a regular (n, k, s, t) LDPC code of rate r=k/n is a (n−k)×n matrix, which has s ones in each column and t>s ones in each row where s<<n and the ones are typically placed randomly in the parity check matrix. When the number of ones in every column is not the same, the code is known as an irregular LDPC code. There are a variety of different known ways for constructing LDPC codes. One efficient heuristic for constructing the parity check matrices of LDPC codes is to use what is referred to in the art as a “bit-filling” algorithm. See J. Campello, D. S. Modha, and S. Rajagopalan, “Designing LDPC Codes Using Bit-Filling,” in IEEE International Conference on Communications (ICC) 2001, pp. 55-59 (October 2001); U.S. Patent Application Publication US 2003/0014718 A1, which are incorporated by reference herein.

Although low density parity check (LDPC) codes were first discovered in 1962, there has been renewed interest in the use of LDPC codes, in particular for potential applications in recent 4G wireless standards. See D. J. C. MacKay and R. M. Neal, “Near Shannon Limit Performance of Low Density Parity Check Codes,” Electronic Letters, Vol. 33, pp. 457-58 (March 1997). LDPC codes, like turbo codes, belong to a class of linear random block error-correction codes whose performance improves as the code length becomes very large and asymptotically approaches the Shannon limit. LDPC codes are seen as attractive, mainly due to possible low decoding complexity and more tractable code design/optimization methodologies. Typically, an LDPC code or turbo code outperforms at low SNR's but may suffer from error floors at high SNR's. One way of addressing this problem is to introduce a concatenated code whose decoder follows the decoding of LDPC or turbo code decoder. This unfortunately introduces a decoding delay.

It would be advantageous to be able to design a code that does not require the exterior assist of concatenated codes. It would also be advantageous to design a code that, while containing error floors while preserving low decoding thresholds, imposes efficient controls on key parameters so as to obtain a better performance tradeoff between low SNR's and high SNR's.

### SUMMARY OF INVENTION

A new technique is herein disclosed for constructing finite-length low-density parity check (LDPC) codes. In accordance with an embodiment of the invention, a parity check matrix is generated by a modified bit-filling approach which advantageously leads to a set of codes with a flexible tradeoff of low decoding thresholds and low error-floors. The code construction approach, in one embodiment, takes advantage of the structure of systematic irregular repeat-accumulate (IRA) codes. The special structure of the codes gives rise to a simple encoding structure and can be exploited to introduce unequal protection for different types of cycles in the factor graph representation of the code. The disclosed embodiments advantageously provide codes with lower encoding complexity and a better performance tradeoff at both low and high signal-to-noise ratios (SNR).

These and other advantages of the invention will be apparent to those of ordinary skill in the art by reference to the following detailed description and the accompanying drawings.

### BRIEF DESCRIPTION OF DRAWINGS

FIG. 1 depicts an illustrative parity check matrix for an irregular LDPC code along with a corresponding bipartite graph representing the parity check nodes and the bit nodes of the code.

FIG. 2 is a flowchart of processing performed in constructing an LDPC code, in accordance with an embodiment of the present invention.

### DETAILED DESCRIPTION

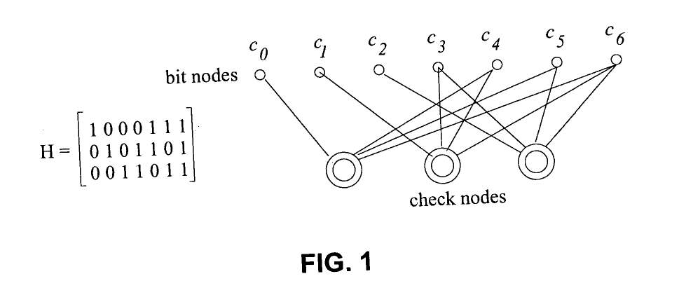

FIG. 1 depicts an illustrative parity check matrix for an irregular low density parity check (LDPC) code. As mentioned in the background, an LDPC code is a linear block code specified by a very sparse parity check matrix. The parity check matrix P of a regular (n, k, s, t) LDPC code of rate r=k/n is a (n−k)×n matrix, which has s ones in each column and t>s ones in each row where s<<n, and the ones are typically placed randomly in the parity check matrix. When the number of ones in every column is not the same, as shown in FIG. 1, the code is known as an irregular LDPC code.

An LDPC code with a parity check matrix can be represented by a bipartite graph which consists of two types of nodes—variable nodes and check codes. Each code bit is a variable node while each parity check or each row of the parity check matrix represents a check node. An edge in the graph is placed between variable node i and check node j if P_{j,i}=1; no parallel edges are allowed between a particular pair of variable node and check node. Each check node is connected to code bits whose sum modulo-2 should be zero. Irregular LDPC codes are specified by two polynomials

$$λ ( x ) = {\sum }_{i = 1}^{{d}_{{l}_{maz}}} {λ}_{i} {x}^{i - 1} and ρ ( x ) = {\sum }_{i = 1}^{{d}_{{r}_{maz}}} {ρ}_{i} {x}^{i - 1} ,$$

where λᵢ is the fraction of edges in the bipartite graph that are connected to variable nodes of degree i, and ρᵢ is the fraction of edges that are connected to check nodes of degree i. Equivalently, the degree profiles can also be specified from the node perspective, i.e., two polynomials

$$\tilde{λ} ( x ) = {\sum }_{i = 1}^{{d}_{{l}_{maz}}} {\tilde{λ}}_{i} {x}^{i - 1}$$

and

$$\tilde{ρ} ( x ) = {\sum }_{i = 1}^{{d}_{{r}_{maz}}} {\tilde{ρ}}_{i} {x}^{i - 1} ,$$

where \tilde{λ}ᵢ is the fraction of variable nodes of degree i, and \tilde{ρ}ᵢ is the fraction of check nodes of degree i. FIG. 1 depicts the parity check matrix for an illustrative irregular (7, 4) code. FIG. 1 also depicts its associated bipartite graph. The degree profiles for this code from the edge perspective are

$$λ ( x ) = \frac{1}{4} + \frac{1}{2} x + \frac{1}{2} {x}^{2} and ρ ( x ) = {x}^{3} .$$

The degree profiles from the node perspective are

$$\tilde{λ} ( x ) = \frac{3}{7} + \frac{3}{7} x + \frac{1}{7} {x}^{2} and \tilde{ρ} ( x ) = {x}^{3} .$$

It is helpful to define a few terms used herein and in the relevant art. The term “cycle” denotes any any un-directional closed loop in a factor graph; since the factor graph of an LDPC code is bipartite, a particular cycle alternately traverses across variable nodes and check nodes. “Cycle-n” denotes a cycle consisting of n edges between variable and check nodes. “Girth” refers to the minimum of cycle lengths of a LDPC code. The girth of any bipartite factor graph is always an even positive integer; in addition, the minimum possible girth is 4. It should be noted that in the discussion herein, without confusion, girth is sometimes parameterized with the degree of variable node; for instance “girth of degree-2 variable node” means the minimum length of all cycles containing degree-2 variable nodes.

The description herein focuses on a particular class of codes referred to as systematic irregular repeat accumulate (IRA) codes. A systematic IRA code is defined by a (n−k)×n parity-check matrix with the form H=[P₁, P₂], where P₁ is a sparse (n−k)×k matrix with smallest column weight being 3 and P₂ is a (n−k)×(n−k) matrix given below

$${P}_{2} = [ \begin{matrix}1 & & & & & & \\ 1 & 1 & & & & & \\ & 1 & 1 & & & & \\ & & & ⋯ & & & \\ & & & & 1 & 1 & \\ & & & & & 1 & 1\end{matrix} ]$$

It can be readily seen that the inverse of P₂ is

$${P}_{2}^{( - 1 )} = [ \begin{matrix}1 & & & & \\ 1 & 1 & & & \\ 1 & ⋮ & 1 & & \\ 1 & ⋮ & ⋮ & 1 & \\ 1 & 1 & 1 & 1 & 1\end{matrix} ]$$

which can be realized by a differential encoder. Furthermore, it is can be shown that the generator matrix G is given as G=[I, P₁^{T}(P₂⁽⁻¹⁾^{T})], where I is a k×k identity matrix and ^{T} denotes matrix transpose. Therefore, an encoder constructed to handle a systematic IRA code advantageously only needs to store and compute a k×(n−k) sparse sub-matrix p₁^{T} (as P₁ is sparse) rather than what is usually a k×n dense matrix G. And in the design and construction of the code, it advantageously suffices to restrict our attention only to P₁, as further explained below.

It can be shown that for infinite-length LDPC codes, once one obtains optimized degree profiles, λ(χ) and ρ(χ); one can randomly construct a parity check matrix P. According to the theorem of concentration around ensemble average and the theorem of convergence to cycle-free ensemble average, such randomly constructed LDPC codes are guaranteed to have vanishing probability of error above the SNR_{min.op} threshold, corresponding to the optimized λ(χ) and ρ(χ)), when its code block-size goes to infinity.

In practice, it is more practical to work with finite-length LDPC codes, e.g., with a block length ranging from a few hundred bits to a few (or tens of) thousand bits. As observed in simulations, if completely randomly generated, finite-length LDPC codes are easily subject to error floors. The effect of error floors can be roughly described with reference to a log-log scale plot of bit error rate (BER)/frame error rate (FER) decoding performance versus SNR. It can be shown that the slope of BER/FER performance becomes flatter at high SNR's.

It is suggested herein that a main reason for error floors, when the code length n>500, is detectable errors of LDPC iterative decoding. LDPC codes can be decoded in a number of known ways. See, e.g., U.S. Pat. Nos. 4,295,218 and 3,542,756, which are both incorporated by reference herein. For example, a decoder can be constructed which applies the sum-product algorithm to the corresponding factor graph; or which uses a maximum a-posteriori (MAP) decoding algorithm, although such a scheme is generally avoided in practice due to prohibitive complexity. The performance of a MAP decoder depends on the distance spectrum of the LDPC codes. The performance of the iterative decoder depends on the properties of the parity-check matrix (the factor graph) as well as on the properties of the LDPC codes.

In general, there are three possible types of errors that may contribute to LDPC error floors of iterative decoding at high SNR's.
“Decoder converges to an invalid codeword”: This corresponds to detectable errors, which are determined by both the code properties and decoding algorithms.
“Decoder converges to a valid but wrong codeword”: This corresponds to undetectable errors. If a MAP decoder is employed, this type of error can be clearly traced back to the small minimum-distance of the codes. When an iterative decoder is employed, the causes for undetectable errors are less clear. Nevertheless, according to simulations conducted by the inventors, when the code length is larger than 1000, one is unable to observe this type of error; when the code length is about 500, this type of undetectable errors occurs with several orders of lower frequency than detectable errors.
“Decoder doesn't converge”: The decoder never converges to an equilibrium. This happens almost exclusively at low SNR's. The inventors only observed very few cases that it happens at high SNR's, and the inventors speculate the reason is that a particular variable is in the path of several cycles and its LLR value updated in contradictory directions.
   From many simulation results, the inventors observed that the detectable errors, i.e., decoder converges to an invalid codeword, dominate the errors (or error-floors) of LDPC codes (with block length above 500) in high SNR regime.

Since an iterative LDPC decoder only updates the extrinsic LLR information of local connections at each iteration, it is advantageous to reduce the detectable errors in the iterative LDPC decoder by enhancing those local code properties, such as local minimum distance, local connectivity, local cycle conditions, etc. Thus, it is advantageous to construct the parity check matrix P for an LDPC code in a manner which takes such conditions into account.

In the construction of finite-length LDPC codes, it would be preferable to achieve a better tradeoff between lower decoding thresholds at low SNR's and lower error floors at high SNR's. It is known in the coding field that strong codes perform well at high SNR's but may lose to weak codes at low SNR's. In the context of LDPC codes and turbo codes, typically an LDPC code or turbo code outperforms at low SNR's, but may suffer from error-floors at high SNR's. One way of solving this problem is to introduce a concatenated code whose decoder follows the decoding of the LDPC or turbo code decoder; but this unfortunately introduces extra decoding delay. It is preferable to focus on a solution that is self-contained without exterior assist of concatenated codes. In addition to containing error-floors while preserving low decoding thresholds, it would be more advantageous to identify and impose efficient controls on some key parameters to obtain better performance tradeoff between low SNR's and high SNR's.

Consider the random construction of a finite-length LDPC code, in particular a systematic IRA code. Assume that optimal degree distributions λ(x) and ρ(x) are already obtained, for example, through density evolution or analysis of EXIT charts. For simplicity, assume that λ(x) can be represented by
λ(x)=λ₁x⁰+λ₂x¹+λ_{w}x^{w-1}.
The first two terms λ₁x⁰+λ₂x¹ correspond to the variable nodes in P₂, note that λ₁x⁰ corresponds to the last column of P₂; and the last term λ_{w}x^{w-1} in fact states that P₁ has a unique column weight of w. Clearly, once P₁ is designed/constructed and together with the constant P₂, the values of λᵢ, ∀i are then determined. Furthermore, assume that ρ(x)=ρᵥ₋₁x^{v-2}+ρᵥx^{v-1}, i.e., rows of P have either weight (v−1) or v; the degree v is implicitly constraint by (λ(x), n, k)—roughly v·(n−k)≈w·n. Based on simulations conducted by the inventors, it is asserted that for short-to-moderate-length LDPC codes (e.g., n=500˜10000) there is only marginal performance loss (<0.2˜0.3 dB) by restricting P₁ to be a matrix with unique-column-weight rather than multiple-column-weight. The λ(x) with richer degree distributions appears to have a non-marginal effect on LDPC performance only when code length becomes very large, e.g., a very large code length (n=10⁶) LDPC code with carefully optimized λ(x) and ρ(x) from density evolution could have a gain around 0.8 dB over (3,6) regular LDPC codes.

An advantageous feature of the finite-length IRA code design and construction technique disclosed herein is the protection of the degree-2 variable nodes. In iterative decoding, the degree-2 variable nodes only connect to two check nodes, which means degree-2 variable nodes have limited extrinsic information exchange with rest of bipartite graph compared to that of higher degree variable nodes. Hence, it is advantageous to give degree-2 variable nodes more protection. On the other hand, the existence of degree-2 variable nodes are very critical for better performance at low SNR's. Intuitively, lower degree check nodes (i.e., less edges in bipartite graph) only exist when there exist certain amount of lower degree variable nodes; and it is the lower degree check nodes that lead to lower decoding thresholds at low SNR's. How to balance the pros and cons of degree-2 variable nodes is a priority issue in constructing LDPC codes with both lower error floors at high SNR's and smaller decoding threshold at low SNR's. (It is interesting to note that it has been shown that a cycle-free LDPC code can hardly have good performance).

In accordance with an embodiment of an aspect of the invention, it is advantageous to apply the following heuristic principles to random construction of IRA parity check matrices P.
1. Forbid cycles which only contains degree-2 variable nodes. In other words, any existing cycle must include at least one degree-w variable node.
2. Maximize the girth of all cycles; and more importantly, the girth of cycles including any degree-2 variable nodes should be larger than the girth of cycles containing all degree-w variable nodes.
   For the three-term λ(x), there are three types of cycles in the factor graph, (1) the cycles containing all degree-2 variable nodes, (2) the cycles containing both degree-2 and degree-w variable nodes, and (3) the cycles containing all degree-w variable nodes. In the order of vulnerability to iterative decoding errors, they are placed as 1,2,3. Due to the structure of P₂, the girth of type 1 cycles has been already maximized, therefore Principle 1 is satisfied. Principle 2 is aimed at improving the girth conditioning of type 2 and type 3 cycles. For λ(x) with more than three terms, we may regroup the terms into three groups, namely the term with power x⁰, the term with power x¹ and rest of the terms. An advantageous procedure of code construction for three-term λ(x) is given next.

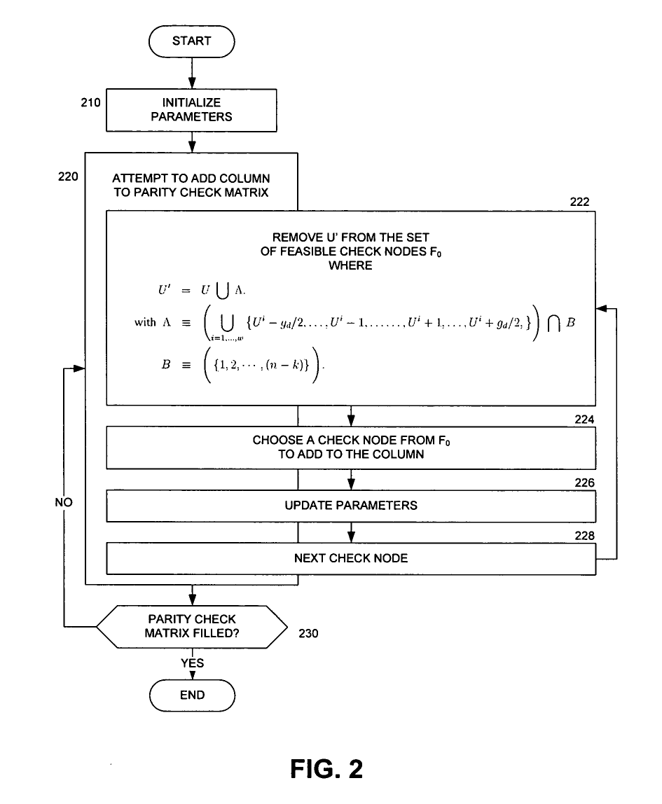

FIG. 2 is a flowchart of processing performed in constructing a finite-length LDPC/IRA code, in accordance with an embodiment of an aspect of the invention.

At step 210, the set of parameters for the design of the finite-length LDPC/IRA code is initialized. One can define the following set of advantageous parameters (n, k, w, v, g, g_{d}), where n is the code length, k is the information-bit length, w is the column weight of sub-matrix P₁, v and v−1 are allowable row weights of parity matrix P, g is the girth of all type (3) cycles, and g+g_{d} is the girth of all type (2) cycles. The goal is to construct a (n−k)×n parity check matrix P which has unique-column-weight w, a row-weight less than or equal to v, and a minimum girth g.

The processing in FIG. 2 proceeds at step 220 by building the parity check matrix P one column at a time. One can view the processing advantageously in a recursive fashion: suppose a matrix P with n′, n′<n, columns that satisfies all the constraints (e.g., column-weight constraint, row-weight constraint and girth constraint) has already been constructed. The issue becomes how to add the (n′+1)-th column to P. The new column is represented by a set U₁ which has a size at most w and is initially empty. The set U₁ is a set of check nodes and, hence, is a subset of |m|≡{1, 2, . . . , n−k}. It is assumed that i check nodes have already been added, 0≦i<w, to U₁. At sub-steps 222-226, an attempt is made to add an (i+1)-th check node to U₁. It may fail, and in that case, the whole processing stops. If it succeeds, the processing proceeds to the next check node.

For a check node 1≦c≦(n−k), let N_{c} denote the set of all check nodes that share a variable node with it. In other words, N_{c} is the set of all check nodes that are exactly two distinct edges away from c. For j≧2, denote

$${U}_{j} = {⋃}_{c ∈ {U}_{j - 1}} {𝒩}_{c} .$$

Let deg(c) denote the degree of the check node c. Let
A={c ε|m|:v−1≦deg(c)≦v}
denote set of check nodes with row-weight of (v−1) or v.

At step 222, the set of feasible check nodes that can be added to U₁ without violating the girth or the check-degree constraint is
F₀=A\U.
U is a set of check nodes that one should avoid adding to U₁ in order to eventually satisfy girth constraints. The processing terminates if F₀ is empty. U₁ can be thought of as the set of check nodes that have been already connected to (n′+1)-th variable node that is being added. The processing of adding a check node c* to U₁ is like adding an edge from the (n′+1)-th variable bit to c*-th check node. Intuitively, there is a path of length 2 from every check node in U₂ to some check node in U₁. Now adding a check node c* to U₁ will create a path of length 2 from c* to every check node in U₁. Hence, to avoid 4-cycles, one should avoid the check nodes in U₂. Continuing in this fashion, one should avoid adding check nodes in Uⱼ to U₁ in order to avoid a cycle of length 2j or smaller. Applying a simple girth constraint of g would entail that the constraint could be met by simply avoiding adding check nodes in the set

$$U = {⋃}_{1 \leq j \leq ( g / 2 ) - 1} {U}_{j} .$$

to U₁.

In accordance with an embodiment of an aspect of the invention, however, it is advantageous to impose differentiated protections on different types of cycles in IRA codes, namely (1) the cycles containing all degree-2 variable nodes, (2) the cycles containing both degree-2 and degree-w variable nodes, and (3) the cycles containing all degree-w variable nodes. Due to the structure of P₂, the girth of type 1 cycles has been already maximized. By taking advantage of the structure of P₂, the set U can be expanded and defined in a manner which results in a girth g for all type (3) cycles and a girth g+g_{d}, g_{d}=2k >0, k ε Z, for all type (2) cycles. For example, one can define an expanded set U′ of original set U as

$${U}^{′} = U ⋃ Λ . \\ with$$

$$Λ ≡ ( {⋃}_{i = 1 , … , w} \{ {U}^{i} - {g}_{d} / 2 , … , {U}^{i} - 1 , … , {U}^{i} + 1 , … , {U}^{i} + {g}_{d} / 2 , \} ) ⋂ B$$

$$B ≡ ( \{ 1 , 2 , … , ( n - k ) \} ) .$$

where Uⁱ denotes the value of the i-th element in set U. It is easy to verify that by avoiding adding check nodes in the set U′ to U₁, the girth of all type (2) cycles is at least g+g_{d}, and the girth of all type (3) cycles is at least g. Correspondingly, the set of feasible check nodes in step 222 should be determined with respect to the expanded set by F₀=A\U′.

At step 224, a check node c* is chosen from F₀ using any advantageous heuristic. At step 226, the check node c* is added to U₁ and updates are made to A, U, and N_{c}. At step 228, processing proceeds to the next check node until i=w. At step 230, processing iterates to the next column in the parity check matrix, and an attempt is made to add the next column to the parity check matrix until failure or until n′=n. To obtain optimized finite-length LDPC (IRA) code design, one can simply exhaust over the parameter combinations, in particular, among (w, g, g_{d}).

FIG. 2 can be seen as a modification of a bit filling procedure described in U.S. Patent Application Publication US 2003/0014718 A1, entitled “SYSTEM AND METHOD FOR GENERATING LOW DENSITY PARITY CHECK CODES USING BIT FILLING,” published on Jan. 16, 2003, which is incorporated by reference herein. Unlike the prior art bit-filling procedures, however, the processing disclosed above manages to lead to flexible and enhanced performance tradeoff between low decoding thresholds and low error floors. It manages to do this by taking advantage of the specific structure of systematic IRA codes described above.

Through Monte Carlo simulations, it can be shown that the optimized IRA codes preserve lower encoding complexity while outperforming regular LDPC codes for FER from 10⁻⁶ to 10⁰, which is advantageous for many wireless communication applications. A variety of observations can be made about the selection of parameters. First, it can be observed that there exists an upper limit of girth g given code parameters (n, k), e.g., the girth 6 is the largest girth possible for a high-rate code where (n=532, k=382). For high-rate codes, there is a tradeoff between the parameters g_{d} and w, namely, the higher column weight w the smaller g_{d} can be. It can also be observed that the column weight w is a critical parameters for the performance tradeoff between lower decoding thresholds (the performance at small SNR's) and lower error-floors (the performance at high SNR's), namely, by forcing a higher column weight, the error-floors are pushed lower at the expense of a performance loss at low SNR's. Simulations show that an IRA design with parameters (w=5, g=6, g_{d}=2) outperforms other designs for a full range of SNR's till FER as low as 10⁻⁶; meanwhile, the encoding complexity of the IRA code is significantly lower than a regular LDPC code. In order to guarantee an even lower error-floors, the column weight w of an IRA code can be further increased, of course, at the expense of reducing g_{d}=0 hence some possible performance loss at low SNR's. In short, the column weight w appears to be a critical parameter for high-rate LDPC performance tradeoff at low and high SNR's.

For mid-rate codes (n=532, k=266), it can be observed that the largest possible girth increases to g=8. Both column weight w and girth g play roles in performance tradeoff, but column weight w is more helpful to obtain low error-floors, as seen that an IRA code of (w=5, g=6, g_{d}=8) outperforms an IRA code of (w=4, g=8, g_{d}=2). While implicit, the differential girth g_{d} as well as overall design procedure of IRA code contribute to the better performance of IRA codes over regular LDPC codes.

For low-rate codes (n=532, k=150), some other interesting observations can be made. First, regular codes appear to perform quite well, a regular LDPC code of (w=3, g=10) performing close to an optimized IRA code of (w=6, g=6, g_{d}=14) at high SNR's. Of course, the price paid by regular codes is the inferior performance at low SNR's and higher encoding complexity. Secondly, the regular LDPC codes and IRA codes seem to take different approaches to achieve good performance. For regular LDPC codes, it is merely by increasing girth g. For IRA codes, as observed from the above discussion of high-rate and mid-rate results, the column weight w is more important than the girth g and the differential girth g_{d} to achieve the better performance tradeoff at low and high SNR's.

It will be appreciated that those skilled in the art will be able to devise numerous arrangements and variations which, although not explicitly shown or described herein, embody the principles of the invention and are within their spirit and scope.

What is claimed is:

1. A method of generating a finite-length low-density parity check (LDPC) code comprising:
(i) storing a parity check matrix, where bits in the parity check matrix are associated with nodes in a factor graph representation of the code; and
(ii) adding bits to the stored parity check matrix subject to constraints which impose unequal protection for different types of cycles in the factor graph representation of the code, thereby resulting in an optimized code represented by the resulting parity check matrix.

2. The method of claim 1 wherein the resulting parity check matrix represents a systematic irregular repeat-accumulate (IRA) code.

3. The method of claim 2 wherein the constraints impose a first girth constraint on a first type of cycles in the factor graph representation of the code and a second girth constraint on a second type of cycles in the factor graph representation of the code, where the second girth constraint is higher than the first girth constraint.

4. The method of claim 2 wherein the constraints impose a first girth constraint on cycles containing all degree-w variable nodes and a second girth constraint on cycles containing both degree-2 and degreew variable nodes, the second girth constraint being higher than the first girth constraint.

5. The method of claim 4 wherein the constraints forbid cycles which only contain degree-2 variable nodes.

6. The method of claim 5 wherein the constraints are met by avoiding adding check nodes in the set U′=U ∪ Λ where
$$U = {⋃}_{1 \leq j \leq ( g / 2 ) - 1} {U}_{j} . \\ and$$
$$Λ ≡ ( {⋃}_{i = 1 , … , w} \{ \begin{matrix}{U}^{ i} - {g}_{ d} / 2 , … , {U}^{ i} - 1 , … , \\ {U}^{ i} + 1 , … , {U}^{ i} + {g}_{ d} / 2 ,\end{matrix} \} ) ⋂ B$$
$$B ≡ ( \{ 1 , 2 , … , ( n - k ) \} ) .$$

7. The method of claim 1 wherein bits are iteratively added to the parity check matrix column-by-column.

8. The method of claim 7 wherein the bits are added to a column in the parity check matrix until a column weight constraint is reached.

9. An encoder which arranges coded symbols in accordance with a finite-length low-density parity check (LDPC) code, the code generated by the method of claim 1.

10. A decoder which interprets coded symbols arranged in accordance with a finite-length low-density parity check (LDPC) code, the code generated by the method of claim 1.
